(19) United States
(12) Patent Application Publication
(10) Pub. No.: US 2023/0038705 A1
(43) Pub. Date: Feb. 9, 2023

(54) POWER CONSUMPTION PATTERN EXTRACTION APPARATUS, POWER CONSUMPTION PATTERN EXTRACTION METHOD AND PROGRAM

(71) Applicant: NIPPON TELEGRAPH AND TELEPHONE CORPORATION, Tokyo (JP)

(72) Inventors: Miho IWAMOTO, Musashino-shi, Tokyo (JP); Masaki KOZAI, Musashino-shi, Tokyo (JP); Hidetoshi TAKADA, Musashino-shi, Tokyo (JP)

(21) Appl. No.: 17/758,813

(22) PCT Filed: Jan. 21, 2020
(86) PCT No.: PCT/JP2020/001920

§ 371 Date: Jul. 14, 2022

(51) Int. Cl. G01R 21/00; G06Q 50/06

(52) U.S. Cl. CPC G01R 21/007; G06Q 50/06

(57) ABSTRACT

A power consumption pattern extraction apparatus according to one embodiment includes a processor and a memory storing program instructions that cause the processor to receive, as an input, a total power consumption for every predetermined time interval over a predetermined time period by a consumer group which consumes power, create a total power consumption matrix that has the total power consumption, received as an input, as elements and has rows and columns corresponding to preset units, perform non-negative matrix factorization on the created total power consumption matrix to create a first factor matrix including basis vectors and a second factor matrix including coefficients for the basis vectors, and extract power consumption patterns and proportions of consumers that consume power in the power consumption patterns from the created first and second factor matrices.

### TECHNICAL FIELD

The present invention relates to a power consumption pattern extraction apparatus, a power consumption pattern extraction method, and a program.

### BACKGROUND ART

In the related art, power demand prediction has been carried out on a somewhat large size, such as within the jurisdiction of an electric power company, for the purpose of system stability or the like. However, in recent years, with the shift to the license system in power distribution, the spread of microgrids, or the like, it has become important to predict power demand in a smaller range.

As a technology for predicting power demand in a small range, a technology that classifies business establishments into types such as a type of office business establishments and a type of factory business establishments by a clustering method and predicts the power demand for each type is known (for example, NPL 1).

### CITATION LIST

### Patent Literature

NPL 1: Takeshi Konno, Satoru Takahashi, Hironobu Kitajima, Yuta Teranishi, Toshihiro Sonoda, “Evaluation of the demand forecasting methods in a facility type,” IPSJ SIG technical reports, Jan. 16, 2013

### SUMMARY OF THE INVENTION

### Technical Problem

However, in the above related art, the optimum prediction method may differ for each type, or even if individual business establishments are of the same type, the prediction results may vary depending on the circumstances of each of the individual business establishments.

An embodiment of the present invention has been made in view of the above points and it is an object of the present invention to easily extract power consumption patterns.

### Means for Solving the Problem

In order to achieve the above object, a power consumption pattern extraction apparatus according to an embodiment includes an input unit configured to receive, as an input, a total power consumption for every predetermined time interval over a predetermined time period by a consumer group which consumes power, a matrix creation unit configured to create a total power consumption matrix that has the total power consumptions received as an input by the input unit as elements and has rows and columns corresponding to preset units, an analysis unit configured to perform non-negative matrix factorization on the total power consumption matrix created by the matrix creating unit to create a first factor matrix including basis vectors, the number of which is equal to a preset number of bases, and a second factor matrix including coefficients for the basis vectors, and an extraction unit configured to extract power consumption patterns, the number of which is equal to the number of bases, and proportions of consumers that consume power in the power consumption patterns from the first and second factor matrices created by the analysis unit.

### Effects of the Invention

Power consumption patterns can be easily extracted.

### BRIEF DESCRIPTION OF DRAWINGS

FIG. 1 is a diagram illustrating an example of an overall configuration of a power consumption pattern extraction apparatus according to the present embodiment.

FIG. 2 is a diagram illustrating an example of a hardware configuration of the power consumption pattern extraction apparatus according to the present embodiment.

FIG. 3 is a flowchart showing an example of a power consumption pattern extraction process according to the present embodiment.

FIG. 4 is a diagram showing an example of total power consumption.

FIG. 5 is a diagram showing an example of a total power consumption matrix.

FIG. 6 is a diagram showing examples of comparison results between extracted patterns and assumed patterns.

FIG. 7 is a diagram showing examples of comparison results between the proportions of the extracted patterns and the proportions of the assumed patterns.

### DESCRIPTION OF EMBODIMENTS

Hereinafter, an embodiment of the present invention will be described. The present embodiment will be described with regard to a power consumption pattern extraction apparatus 10 that receives a total power consumption of a consumer group as an input and extracts power consumption patterns and proportions of consumers which consume power in the power consumption patterns through non-negative matrix factorization (NMF). Consumers refer to entities which consume (demand) power such as, for example, offices, factories, residences, or various kinds of equipment or facilities. A consumer group refers to a set of consumers. The size of the consumer group is not particularly limited.

Overall Configuration

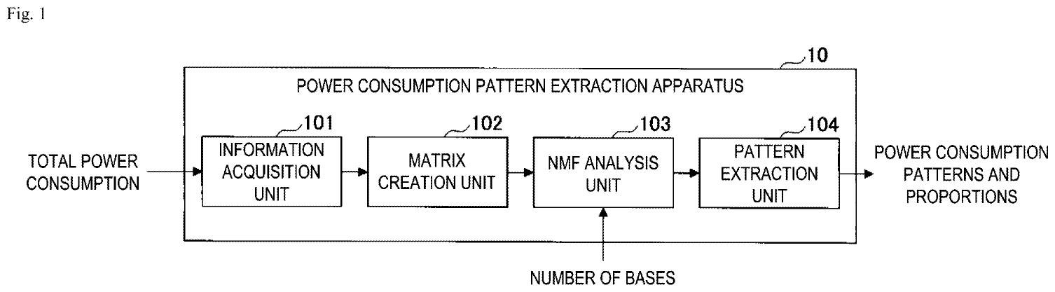

First, an overall configuration of a power consumption pattern extraction apparatus 10 according to the present embodiment will be described with reference to FIG. 1. FIG. 1 is a diagram illustrating an example of the overall configuration of the power consumption pattern extraction apparatus 10 according to the present embodiment.

As illustrated in FIG. 1, the power consumption pattern extraction apparatus 10 according to the present embodiment includes an information acquisition unit 101, a matrix creation unit 102, an NMF analysis unit 103, and a pattern extraction unit 104.

The information acquisition unit 101 acquires (receives as an input) a total power consumption of a consumer group. Here, the information acquisition unit 101 receives, as an input, the total power consumption of the consumer group for every predetermined time interval (for example, every 30 minutes) over a predetermined time period (for example, 9 days). The values of the total power consumption are non-negative values.

The matrix creation unit 102 creates data in the form of a matrix (hereinafter referred to as a “total power consumption matrix”) whose elements are the total power consumptions received as an input by the information acquisition unit 101. Here, the matrix creation unit 102 creates a total power consumption matrix with rows and columns corresponding to preset units. For example, the matrix creation unit 102 creates a total power consumption matrix with columns corresponding to days and rows corresponding to hours. In this case, for example, when the total power consumption of the consumer group for every 30 minutes over 9 days is received as an input by the information acquisition unit 101, the matrix creation unit 102 creates a total power consumption matrix of 48 rows and 9 columns, the rows corresponding to time intervals of 30 minutes and the columns corresponding to the first to ninth days.

The NMF analysis unit 103 decomposes the total power consumption matrix into a product of a first factor matrix composed of basis vectors and a second factor matrix composed of coefficients (weights) for the basis vectors through NMF using the number of bases which is a preset parameter. For example, the total number of assumed power consumption patterns is set as the number of bases.

The pattern extraction unit 104 extracts power consumption patterns and proportions of consumers which have consumed power in the power consumption patterns from the first and second factor matrices that the NMF analysis unit 103 has obtained through NMF. Here, the basis vectors represent the power consumption patterns and the coefficients for the basis vectors represent the proportions of the power consumption patterns. The power consumption patterns are time-series patterns representing the tendency of consumers to consume electricity, examples of which are patterns such as that in which power consumption is high (or low) in a specific time zone or that in which power consumption is high (or low) in a specific month or season.

Hardware Configuration

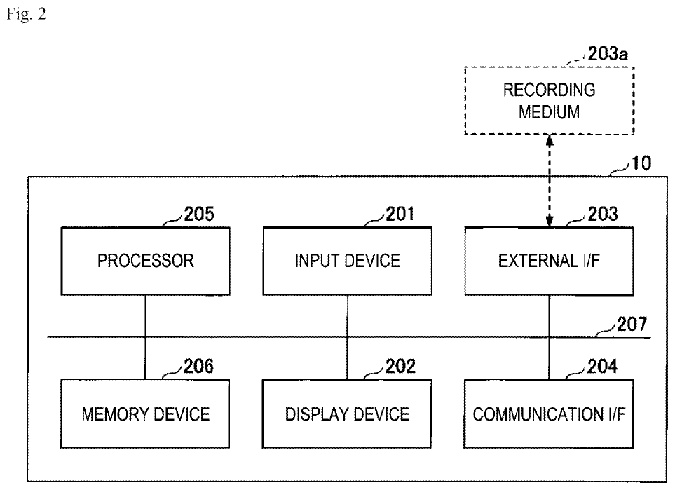

Next, a hardware configuration of the power consumption pattern extraction apparatus 10 according to the present embodiment will be described with reference to FIG. 2. FIG. 2 is a diagram illustrating an example of the hardware configuration of the power consumption pattern extraction apparatus 10 according to the present embodiment.

As illustrated in FIG. 2, the power consumption pattern extraction apparatus 10 according to the present embodiment is realized by a general computer or a computer system, and includes an input device 201, a display device 202, an external interface (I/F) 203, a communication interface (I/F) 204, a processor 205, and a memory device 206. These hardware components are communicatively connected via a bus 207.

The input device 201 is, for example, a keyboard, a mouse, or a touch panel. The display device 202 is, for example, a display. The power consumption pattern extraction apparatus 10 may not include at least one of the input device 201 and the display device 202.

The external interface 203 is an interface with an external device. The external device is a recording medium 203a or the like. The power consumption pattern extraction apparatus 10 can perform reading, writing, or the like from or to the recording medium 203a via the external interface 203. The recording medium 203a may store one or more programs that implement the functional units (the information acquisition unit 101, the matrix creation unit 102, the NMF analysis unit 103, and the pattern extraction unit 104) of the power consumption pattern extraction apparatus 10.

Examples of the recording medium 203a include a compact disc (CD), a digital versatile disc (DVD), a secure digital (SD) memory card, and a universal serial bus (USB) memory card.

The communication interface 204 is an interface for connecting the power consumption pattern extraction apparatus 10 to a communication network. One or more programs that implement each functional unit of the power consumption pattern extraction apparatus 10 may be acquired (downloaded) from a predetermined server device or the like via the communication interface 204.

The processor 205 is, for example, any of various arithmetic units such as a central processing unit (CPU). Each functional unit included in the power consumption pattern extraction apparatus 10 is implemented, for example, by processing that one or more programs stored in the memory device 206 or the like cause the processor 205 to execute.

The memory device 206 is, for example, any of various storage devices such as a hard disk drive (HDD), a solid state drive (SSD), a random access memory (RAM), a read only memory (ROM), or a flash memory.

By having the hardware configuration illustrated in FIG. 2, the power consumption pattern extraction apparatus 10 according to the present embodiment can realize a power consumption pattern extraction process that will be described below. The hardware configuration illustrated in FIG. 2 is an example and the power consumption pattern extraction apparatus 10 may have another hardware configuration. For example, the power consumption pattern extraction apparatus 10 may have a plurality of processors 205 or may have a plurality of memory devices 206.

Power Consumption Pattern Extraction Process

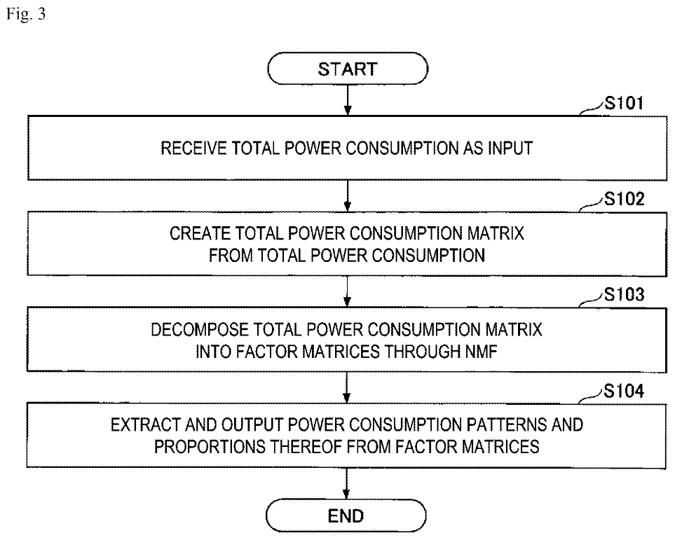

Next, a process of extracting power consumption patterns and proportions thereof from a total power consumption by the power consumption pattern extraction apparatus 10 according to the present embodiment (a power consumption pattern extraction process) will be described with reference to FIG. 3. FIG. 3 is a flowchart showing an example of the power consumption pattern extraction process according to the present embodiment.

Step S101: First, the information acquisition unit 101 receives, as an input, a total power consumption of a consumer group. The information acquisition unit 101 may receive, as an input, a total power consumption of a consumer group from any input source. For example, the information acquisition unit 101 may receive, as an input, a total power consumption stored in the memory device 206 or may receive, as an input, a total power consumption from a server device or the like that is connected to the power consumption pattern extraction apparatus 10 via a communication network.

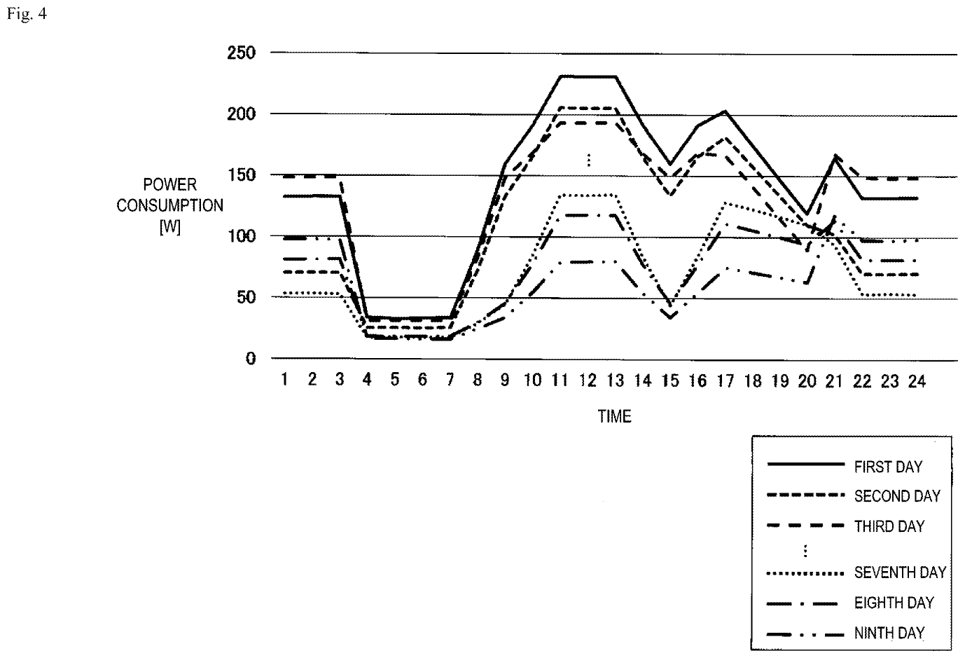

Here, in the present embodiment, it is assumed that a total power consumption shown in FIG. 4 has been received as an input by the information acquisition unit 101 as an example. The total power consumption illustrated in FIG. 4 is a total power consumption of a consumer group for every 30 minutes over 9 days.

The information acquisition unit 101 can receive, as an input, a power consumption of a consumer group for every any time interval over any time period. The time period can be set in various time units other than days such as, for example, weeks, months, or years. The time interval can be set in various time units other than every 30 minute such as, for example, every hour, every two hours, every day, every week, every month, or every year. More specifically, the information acquisition unit 101 can receive, as an input, a power consumption of a consumer group, for example, for every Ω minutes (or every Ω hours, every Ω days, every Ω weeks, every Ω months, every Ω years, etc.) over T days (or T months, T weeks, T years, etc.).

Step S102: Next, the matrix creation unit 102 creates a total power consumption matrix that has the total power consumptions input in step S101 as elements and has rows and columns corresponding preset units.

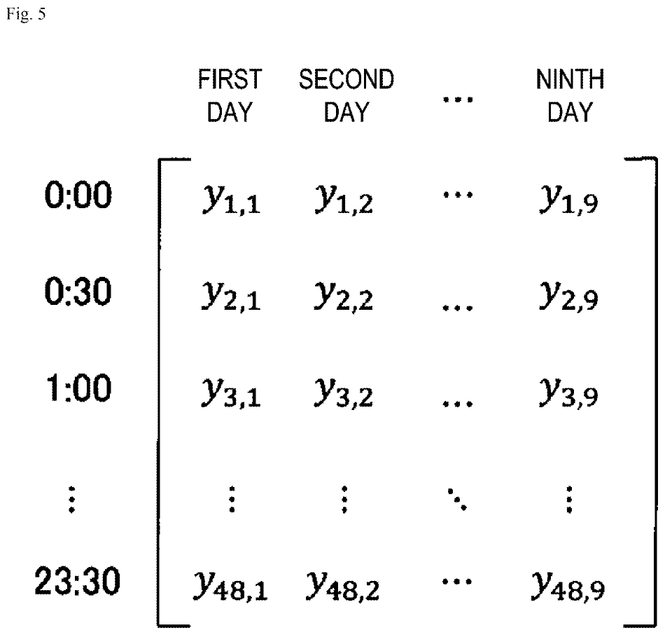

Here, in the present embodiment, it is assumed that the matrix creation unit 102 has created the total power consumption matrix shown in FIG. 5 as an example. The total power consumption matrix shown in FIG. 5 is a total power consumption matrix of 48 rows and 9 columns with the rows corresponding to time intervals of 30 minutes and the columns corresponding to days. That is, a t-th column of the total power consumption matrix shown in FIG. 5 (where 1≤t≤9) is composed of 48 total power consumptions y_{1,t} to y_{48,t} of time intervals of 30 minutes from 0:00 to 23:30 on a t-th day.

However, the units in which the rows and columns of the total power consumption matrix are set may differ depending on the time interval or the time period of the total power consumption input in step S101 above. For example, when the total power consumption input in step S101 is a total power consumption for every day over 10 years, a matrix of 365 rows and 10 columns with each row corresponding to one day and each column corresponding to one year can be conceived as a total power consumption matrix.

Step S103: Next, the NMF analysis unit 103 decomposes the total power consumption matrix into a product of a first factor matrix and a second factor matrix through NMF using the number of bases which is a preset parameter.

Here, NMF obtains H and U such that Y˜HU (that is, obtains H and U such that HU approximates Y) when decomposing a total power consumption matrix Y of Ω rows and T columns into a product of a first factor matrix H of Ω rows and K columns and a second factor matrix U of K rows and T columns. Here, K is the number of bases.

Such H and U can be obtained, for example, by using D shown in the following equation (1) as an objective function and minimizing the value of the objective function D.

$$\begin{matrix}[ Math . 1 ] & \\ D = ‖ Y - H U ‖ = {\sum }_{ω , k} {\vert {Y}_{ω , t} - {\sum }_{k} {H}_{ω , k} {U}_{k , t} \vert}^{2} & ( 1 )\end{matrix}$$

Here, Y_{ω,t}≥0 is an (ω, t) element of the total power consumption matrix Y, H_{ω,k}≥0 is an (ω, k) element of the first factor matrix H, and U_{k,t}≥0 is a (k, t) element of the second factor matrix U.

The following equations (2) and (3) are used as update formulas for H_{ω,k} and U_{k,t}.

$$\begin{matrix}[ Math . 2 ] & \\ {H}_{ω , k} = {H}_{ω , k} \frac{{[ Y {U}^{τ} ]}_{ω , k}}{{[ H U {U}^{τ} ]}_{ω , k}} & ( 2 )\end{matrix}$$

$${U}_{k , t} = {U}_{k , t} \frac{{[ {H}^{τ} Y ]}_{k , t}}{{[ {H}^{τ} H U ]}_{k , t}} \qquad ( 3 )$$

Here, τ represents the transpose.

The first factor matrix H and the second factor matrix U can be obtained by repeatedly applying the update formulas shown in the above equations (2) and (3) until a predetermined end condition is satisfied. Examples of the end condition include that the value of the objective function D has converged (that is, the amount of change in the value of the objective function D before and after a repetition is a predetermined first threshold value or less), that the value of the objective function D is a second threshold value or less, and the number of repetitions is a predetermined number or more.

Here, although NMF using the Euclidean distance as the norm of the objective function D shown in equation (2) is shown above as an example, the present invention is not limited to this. Other distances (for example, the Itakura-Saito distance) may be used as the norm of the objective function D shown in equation (2). For details of NMF using the Euclidean distance, see, for example, Reference 1 (D. D. Lee and H. S. Seung, “Learning the parts of objects with nonnegative matrix factorization,” Nature, vol. 401, pp. 788-791, 1999). For details of NMF using the Itakura-Saito distance, see, for example, Reference 2 (C. Fevotte, N. Bertin, and J.-L. Durrieu, “Nonnegative matrix factorization with the Itakura-Saito divergence. With application to music analysis,” Neural Computation, vol. 21, no. 3, March 2009).

In the present embodiment, the total power consumption matrix Y is decomposed into the first factor matrix H and the second factor matrix U through NMF. However, for example, the total power consumption matrix Y may be extended to a tensor by adding some information (such as information indicating, for example, an area where power is consumed) to the total power consumption matrix Y and this tensor Y may then b e decomposed into a plurality of factor matrices through non-negative tensor factorization (NTF). For example, when the power consumption matrix Y is extended to a cubic tensor Y by adding information indicating an area where power is consumed, this tensor Y is decomposed into a product of three factor matrices.

Step S104: Next, the pattern extraction unit 104 extracts power consumption patterns and proportions of consumers which have consumed power in the power consumption patterns from the first and second factor matrices obtained in step S103 above and outputs the extracted power consumption patterns and proportions of consumers. Here, basis vectors constituting the first factor matrix represent the power consumption patterns and elements (coefficients for the basis vectors) constituting the second factor matrix represent the proportions of the power consumption patterns. The output destination of the power consumption patterns and the proportions thereof may be any output destination. For example, the pattern extraction unit 104 may output (store) the power consumption patterns and the proportions thereof to (in) the memory device 206 or may output (transmit) the power consumption patterns and the proportions thereof to a device, a terminal, or the like that is connected to the power consumption pattern extraction apparatus 10 via the communication network.

That is, when the first factor matrix H is expressed as H=[h₁, . . . , h_{K}] using Ω-dimensional column vectors h₁, . . . , h_{K}, h₁, . . . , h_{K} are basis vectors and the basis vectors h₁, . . . , h_{K} represent K power consumption patterns. Thus, the pattern extraction unit 104 extracts K power consumption patterns by extracting K basis vectors from the first factor matrix.

Further, when the second factor matrix U is expressed as U=[u₁, . . . , u_{T}] using K-dimensional column vectors u₁, . . . , u_{T}, uₜ (where 1≤t≤T) represents the proportions of power consumption patterns on the day corresponding to t (more generally, the day, month, year, or the like corresponding to the t-th column of the power consumption matrix Y). That is, when uₜ=[u₁ₜ, . . . u_{Kt}]^{τ}, uₖₜ (where 1≤k≤K) represents the proportion of consumers which have consumed power in a power consumption pattern corresponding to k on the day corresponding to t.

The elements uₖₜ of each K-dimensional vector uₜ may be normalized such that 0≤uₖₜ≤1 by dividing the elements uₖₜ, for example, by the sum uᵢₜ+ . . . +u_{Kt} of all elements of the vector uₜ. Alternatively, the elements uₖₜ of each K-dimensional vector uₜ may be normalized, for example, by dividing the elements uₖₜ by a predetermined value. The predetermined value may be, for example, the sum of total power consumption s of the consumer group on the t-th day or the maximum of the total power consumptions of the consumer group over the T days.

As described above, the power consumption pattern extraction apparatus 10 according to the present embodiment can receive the a total power consumption of a consumer group of any size as an input and extract power consumption patterns of the consumer group and proportions of consumers which have consumed power in the power consumption patterns. Therefore, by using the power consumption pattern extraction apparatus 10 according to the present embodiment, it is possible to easily obtain appropriate power consumption patterns of a consumer group and proportions of the power consumption patterns, regardless of the size of the consumer group.

Thus, it is possible to easily perform power demand prediction or the like by using the power consumption patterns and the proportions thereof extracted by the power consumption pattern extraction apparatus 10 according to the present embodiment. For example, it is possible to predict power demand by summing the products of power consumption patterns and coefficients for the power consumption patterns. In this case, because the problem of power demand prediction is replaced with the problem of predicting the coefficient for each power consumption pattern, the power demand can be easily calculated using a known method regardless of the size of the consumer group.

Evaluation

Here, power consumption patterns and proportions thereof extracted by the power consumption pattern extraction apparatus 10 according to the present embodiment are evaluated. In the following, power consumption patterns extracted by the power consumption pattern extraction apparatus 10 will be referred to as “extracted patterns” and power consumption patterns which are correct answers known in advance will be referred to as “assumed patterns.” It is also assumed that the assumed patterns are a “morning/evening pattern” in which power consumption increases in the morning and evening hours, a “midday pattern” in which power consumption increases in the midday hours, and a “midnight pattern” in which power consumption increases in the midnight hours.

As an example, it is assumed that the a total power consumption of a consumer group for every hour over 9 days is input to the power consumption pattern extraction apparatus 10 and the number of bases is K=3. In this case, the total power consumption matrix Y has 24 rows and 9 columns, the first factor matrix H has 24 rows and 3 columns, and the second factor matrix has 3 rows and 9 columns.

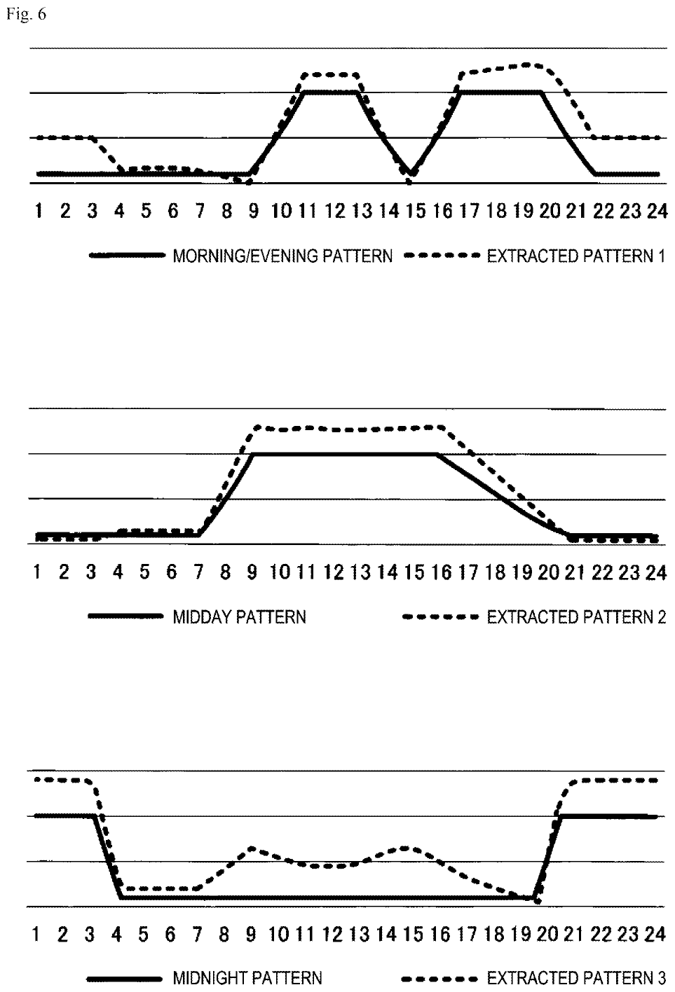

Here, FIG. 6 shows results of comparing extracted patterns 1, 2, and 3 with the assumed patterns, where the extracted pattern 1 is a pattern closest in shape to the morning/evening pattern among the extracted patterns represented by the three basis vectors of the first factor matrix H, the extracted pattern 2 is a pattern closest in shape to the midday pattern, and the extracted pattern 3 is a pattern closest in shape to the midnight pattern. In FIG. 6, the horizontal axis represents time and the vertical axis represents power consumption.

As shown in FIG. 6, the extracted pattern 1 closely approximates the morning/evening pattern, the extracted pattern 2 closely approximates the midday pattern, and the extracted pattern 3 closely approximates the midnight pattern. Thus, it can be seen that the power consumption pattern extraction apparatus 10 according to the present embodiment obtains highly accurate power consumption patterns.

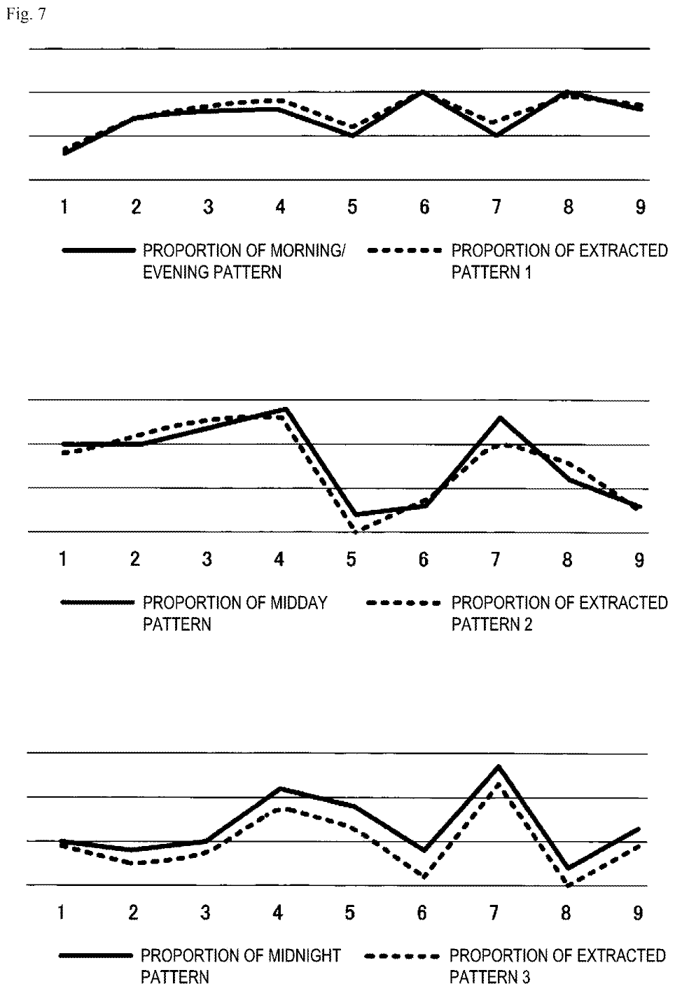

Next, FIG. 7 shows results of comparing the proportions of the extracted patterns on the first to ninth days, which are represented by the elements of the nine column vectors constituting the second factor matrix U, with the proportions of the assumed patterns which are correct answers known in advance. In FIG. 7, the horizontal axis represents the day and the vertical axis represents the proportion.

As shown in FIG. 7, the proportion of the extracted pattern 1 closely approximates the proportion of the morning/evening pattern, the proportion of the extracted pattern 2 closely approximates the proportion of the midday pattern, and the proportion of the extracted pattern 3 closely approximates the proportion of the midnight pattern. Thus, it can be seen that the power consumption pattern extraction apparatus 10 according to the present embodiment obtains highly accurate proportions of the power consumption patterns.

The present invention is not limited to the above embodiment described specifically and various modifications or changes, combinations with existing techniques, and the like can be made without departing from the description of the claims.

### REFERENCE SIGNS LIST

10 Power consumption pattern extraction apparatus
101 Information acquisition unit
102 Matrix creation unit
103 NMF analysis unit
104 Pattern extraction unit

1. A power consumption pattern extraction apparatus comprising:
a processor; and
a memory storing program instructions that cause the processor to:
receive, as an input, a total power consumption for every predetermined time interval over a predetermined time period by a consumer group which consumes power;
create a total power consumption matrix that has the total power consumptions, received as an input, as elements and has rows and columns corresponding to preset units;
perform non-negative matrix factorization on the created total power consumption matrix to create a first factor matrix including basis vectors, the number of which is equal to a preset number of bases, and a second factor matrix including coefficients for the basis vectors; and
extract power consumption patterns, the number of which is equal to the number of bases, and proportions of consumers that consume power in the power consumption patterns from the created first and second factor matrices.

2. The power consumption pattern extraction apparatus according to claim 1, wherein the program instructions further cause the processor to perform-non-negative tensor factorization on a tensor obtained by adding predetermined information to the total power consumption matrix to create a plurality of factor matrices including the first and second factor matrices, and
extract the power consumption patterns and the proportions from the plurality of factor matrices.

3. The power consumption pattern extraction apparatus according to claim 1, wherein the program instructions further cause the processor to perform predetermined normalization on the elements constituting the second factor matrix and extract the normalized elements as the proportions.

4. The power consumption pattern extraction apparatus according to claim 1, wherein the program instructions further cause the processor to create a total power consumption matrix having rows corresponding to units of one of hours, days, weeks, months, or years and columns corresponding to units of one of hours, days, weeks, months, or years.

5. The power consumption pattern extraction apparatus according to claim 1, wherein the program instructions further cause the processor to extract the basis vectors constituting the first factor matrix as the power consumption patterns.

6. A power consumption pattern extraction method comprising:
by a computer, receiving, as an input, a total power consumption for every predetermined time interval over a predetermined time period by a consumer group which consumes power;
by the computer, creating a total power consumption matrix that has the total power consumptions received as an input in the receiving as elements and has rows and columns corresponding to preset units;
by the computer, performing non-negative matrix factorization on the total power consumption matrix created in the creating to create a first factor matrix including basis vectors, the number of which is equal to a preset number of bases, and a second factor matrix including coefficients for the basis vectors; and
by the computer, extracting power consumption patterns, the number of which is equal to the number of bases, and proportions of consumers that consume power in the power consumption patterns from the first and second factor matrices created in the performing.

7. A non-transitory computer-readable storage medium that stores therein a program for causing a computer including a memory and a processor to operate as the power consumption pattern extraction apparatus according to claim 1.
